(19) United States
(12) Patent Application Publication
(10) Pub. No.: US 2026/0278185 A1
(43) Pub. Date: Sep. 17, 2026

(54) System and Method for Creation of Parametric 3D CAD Models

(71) Applicant: ABB Schweiz AG, Baden (CH)

(72) Inventors: Matthew Hetrich, Cary, NC (US); Stefan Rakuff, Garner, NC (US); Premith Kumar Chilukuri, Raleigh, NC (US)

(73) Assignee: ABB Schweiz AG, Baden (CH)

(21) Appl. No.: 19/080,292

(22) Filed: Mar. 14, 2025

(51) Int. Cl. G06F 30/12; G06F 30/27

(52) U.S. Cl. CPC G06F 30/12; G06F 30/27

(57) ABSTRACT

A method for generating a three-dimensional (3D) model of a monolithic part includes performing a plurality of generative actions using a plurality of thought tokens to generate a primary model based on a prompt received at the geometric modelling agent. The primary model is converted to executable code to generate a 3D computer-aided design (CAD) model associated with the primary model. Parametric equations are generated to represent the 3D CAD model based on the executable code. An evaluation metric associated with the 3D CAD model rendered based on the parametric equations is calculated, and the 3D parametric model is generated based on determining that the evaluation metric of the 3D CAD model exceeds a predetermined threshold.

### FIELD

The present disclosure relates to large language models. In particular, the present disclosure relates to generating parametric three-dimensional (3D) models using large language models (LLMs).

### BACKGROUND

Technical drawings play a crucial role in communicating design and manufacturing specifications in industry and engineering, while 3D CAD models are invaluable for checking component fitment and potential collisions in assemblies. The modern design process typically begins with creating a 3D CAD model to develop the concept, followed by deriving a technical drawing with necessary tolerances and dimensions. However, many technical drawings still in use predate 3D CAD technology, lacking corresponding 3D models and making it difficult to validate component fitment within assemblies.

### SUMMARY

A first aspect of the present disclosure provides a method for generating a three-dimensional (3D) model of a monolithic part, the method comprising: a. performing a plurality of generative actions using a plurality of thought tokens to generate a primary model based on a prompt received at the geometric modelling agent; b. converting the primary model to executable code to generate a 3D computer-aided design (CAD) model associated with the primary model; c. generating parametric equations to represent the 3D CAD model based on the executable code; d. calculating an evaluation metric associated with the 3D CAD model rendered based on the parametric equations; and e. generating the parametric 3D model based on determining that the evaluation metric of the 3D CAD model exceeds a predetermined threshold.

According to an implementation of the first aspect, based on determining that the evaluation metric associated with the 3D CAD model is less than the predetermined threshold, the method further comprises: generating feedback based on the calculated evaluation metric; modifying the plurality of thought tokens to generate a modified plurality of thought tokens based on the feedback; revising the executable code based on the modified plurality of thought token to obtain revised executable code; regenerating the parametric equations based on the revised executable code to obtain revised parametric equations; and calculating a revised evaluation metric associated with a new 3D CAD model rendered based on the revised parametric equations.

According to an implementation of the first aspect, steps a.-e. are repeated until the evaluation metric is less than the predetermined threshold.

According to an implementation of the first aspect, the 3D CAD model is generated by interfacing with an open-source CAD software using application programming interface (API) calls.

According to an implementation of the first aspect, generating the primary model based on the thought tokens comprises orienting a global system with axes of symmetry.

According to an implementation of the first aspect, generating the primary model based on the thought tokens comprises creating base primitives, and wherein the base primitives are created by extruding or revolving open or closed 3D sketches, respectively.

According to an implementation of the first aspect, generating the primary model based on the thought tokens comprises generating secondary primitives and performing Boolean operations.

According to an implementation of the first aspect, generating the primary model based on the thought tokens comprises defining types, locations, and size parameters of various components the monolithic part.

According to an implementation of the first aspect, generating the primary model based on the thought tokens comprises defining circular or linear patterns of repeating instances of a geometric feature with number of instances, spacing, and skipped instances.

A second aspect of the present disclosure provides a system for generating a three-dimensional (3D) model of a monolithic part, the system comprising: a controller, configured to: a. perform a plurality of generative actions using a plurality of thought tokens to generate a primary model based on a prompt received at the geometric modelling agent; b. convert the primary model to executable code to generate a 3D computer-aided design (CAD) model associated with the primary model; c. generate parametric equations to represent the 3D CAD model based on the executable code; d. calculate an evaluation metric associated with the 3D CAD model rendered based on the parametric equations; and e. generate the parametric 3D model based on determining that the evaluation metric of the 3D CAD model exceeds a predetermined threshold.

A third aspect of the present disclosure provides a tangible, non-transitory computer-readable medium for generating a three-dimensional (3D) model of a monolithic part, the computer-readable medium having instructions thereon, which, upon being executed by one or more processors, provides for execution of the following steps: a. performing a plurality of generative actions using a plurality of thought tokens to generate a primary model based on a prompt received at the geometric modelling agent; b. converting the primary model to executable code to generate a 3D computer-aided design (CAD) model associated with the primary model; c. generating parametric equations to represent the 3D CAD model based on the executable code; d. calculating an evaluation metric associated with the 3D CAD model rendered based on the parametric equations; and e. generating the parametric 3D model based on determining that the evaluation metric of the 3D CAD model exceeds a predetermined threshold.

### BRIEF DESCRIPTION OF THE DRAWINGS

Subject matter of the present disclosure will be described in even greater detail below based on the exemplary figures. All features described and/or illustrated herein may be used alone or combined in different combinations. The features and advantages of various embodiments will become apparent by reading the following detailed description with reference to the attached drawings, which illustrate the following:

FIG. 1 illustrates a simplified diagram of an exemplary system to generate parametric three-dimensional (3D) CAD models, according to one or more examples of the present disclosure;

FIGS. 2A-2D illustrate a simplified diagram of a process of generating parametric three-dimensional (3D) CAD models, according to one or more examples of the present disclosure;

FIG. 3 is a simplified diagram of a process of generating parametric three-dimensional (3D) CAD models, according to one or more examples of the present disclosure; and

FIG. 4 is a simplified block diagram of one or more devices or systems within the exemplary environment of FIG. 1, according to one or more examples of the present disclosure.

### DETAILED DESCRIPTION

Examples of the present application will now be described more fully hereinafter with reference to the accompanying FIGs., in which some, but not all, examples of the application are shown. Indeed, the application may be exemplified in different forms and should not be construed as limited to the examples set forth herein; rather, these examples are provided so that the application will satisfy applicable legal requirements. Where possible, any terms expressed in the singular form herein are meant to also include the plural form and vice versa, unless explicitly stated otherwise. Also, as used herein, the term “a” and/or “an” shall mean “one or more” even though the phrase “one or more” is also used herein. Furthermore, when it is said herein that something is “based on” something else, it may be based on one or more other things as well. In other words, unless expressly indicated otherwise, as used herein “based on” means “based at least in part on” or “based at least partially on”.

Conventionally, a 3D CAD model is usually the first step to develop a concept when designing a component. A technical drawing is later derived from the 3D CAD model with the required tolerancing and dimensioning to ensure the functionality of the component. A large number of technical drawings today predate the adaptation of 3D CAD modeling technology. For such drawings, there are no corresponding 3D CAD models, and so it is nearly impossible to validate fitment of components in the context of assembly. Corresponding 3D CAD models of all components are created to ensure that there are no problems with collisions and interferences in the assembly.

Early versions of CAD model generators based on artificial intelligence (AI) used variational autoencoders or 3D GANS. More recently, the reasoning capabilities of LLMs have been used in a one-shot approach to create conceptual 3D CAD models based on user prompts. Most approaches generate the models via generating scripts or macros with open source or proprietary CAD modeling functions.

The present disclosure automates the creation of 3D CAD models from technical drawings using large language models (LLMs). In accordance with embodiments of the present disclosure, an agentic workflow instead of a one-shot approach is used to create CAD models. A vision language model (VLM) is used to receive a prompt of a technical drawing to generate a 3D CAD model. The VLM interprets the technical drawing to extract semantic relationships such as text and numbers, feature sizes, dimension symbols, and different styles of curves and lines.

In some embodiments, thought tokens may be used to automatically create a plan to generate the 3D CAD model. For example, thought tokens may be used to analyze the interpretation provided by the VLM to prepare 3D primitives. The 3D primitives are modified by addition additional geometric features for refinement. Each step of adding 3D primitives and adding additional geometric features is checked using secondary agents or LLMs with the ability to execute functions and eliminate under-defined, zero-volume, and circularly referenced geometry.

The 3D CAD model is generated in the form of scrips using open-source or proprietary libraries such as OpensCAD, FreeCAD, CadQuery, or the SolidWorks API. In some embodiments, the open-source libraries include predefined functions to simplify the creation of various other features such as threaded holes, slots, and chamfers.

The generated 3D CAD model is evaluated and rejected if it does not meet minimum threshold requirements on accuracy. In accordance with some embodiments, definitions of minimum threshold requirements may be part of the CAD system used to generate the 3D CAD model. The definitions of the 3D CAD model may be parameterized, and parameter values may depend on a size of the part to be modeled or accuracy requirements of the part to be modeled. The parameter values may be set by agents accordingly. One example of a minimum threshold requirement on accuracy includes the ability to resolve a shallow (small draft angle) taper feature along the outer surface of a shaft that forms a press fit interface with rotor laminations. The 3D CAD model may also include geometric dimension and tolerance (GD&T) information or a bill of material (BOM). To interpret this type of information from the drawing, a model fine-tuned on a corpus of similar part drawings may be required. For example, a VLM that is fine-tuned using a large number of similar parts may be used to interpret information from the drawing. In some embodiments, the VLM could be fine-tuned using a large corpus of shaft drawings and CAD models.

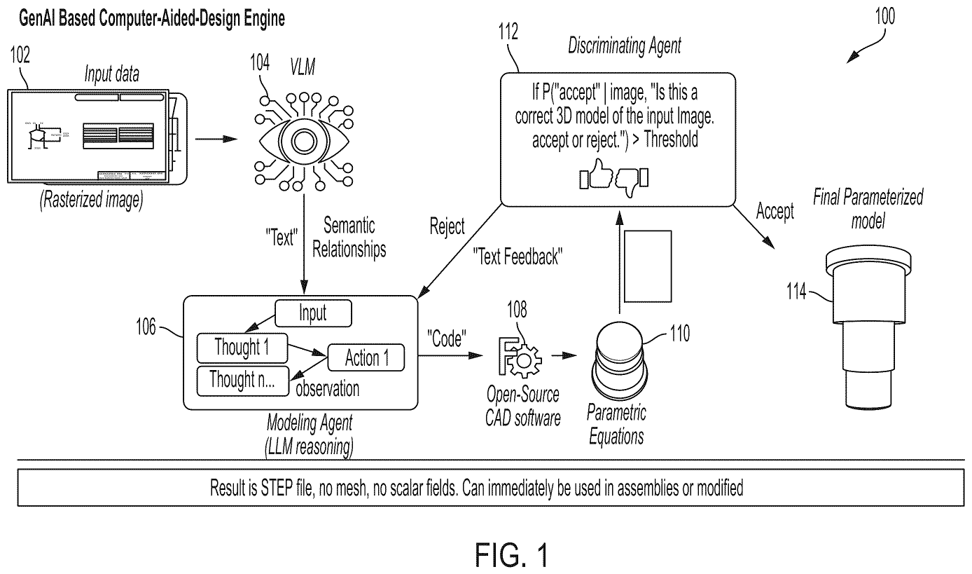

FIG. 1 illustrates a simplified diagram of an exemplary system to generate parametric three-dimensional (3D) CAD models, according to one or more examples of the present disclosure. System 100 of FIG. 1 includes a vision language model (VLM) 104, a modelling agent 106, and a discriminating agent 112.

In order to generate the 3D CAD model, an input prompt 102 is provided to the vision language model 102. In some embodiments, the input prompt 102 may be a technical drawing of a part, for which the 3D CAD model is to be generated. In some alternate embodiments, the input prompt 102 may be a textual description of a part, for which the 3D CAD model is to be generated.

The VLM 104 analyzes the technical drawing to generate a description associated with the technical drawing. For example, the VLM 104 may review the provided technical drawing and determine that the technical drawings include various components. The VLM 104 may determine semantic relationships between the various components of the technical drawing. In some cases, the technical drawing may also include various description information such as scaling, units, materials, and tolerances. The technical drawing may also include numbers for dimension, extension, leader lines. Symbols may be provided in the technical drawing for radii, diameters, counterbores, countersinks, depths, and other elements. The technical drawing may also have datum control frames and symbols for form, orientation, and location, and different styles of curves and lines. The VLM 104 may extract the aforementioned semantic relationships and description information from the provided technical drawing and condense it in a text description of the technical drawing.

The semantic relationships and description extracted from the technical drawing by the VLM 104 is provided to the modelling agent 106 along with a plurality of thought tokens. For example, the thought tokens provided to the modelling agent 106, may include tokens such as: T1—Identify any symmetry by looking for dash-dotted lines; T2—Identify largest geometric primitive as a base feature, and neglect small features; T3—Identify secondary primitives to be combined or removed from the first primitive; T4—Using the feature callout symbols (diameter, counterbores, threads, etc.); T5: Identify any chamfers and fillets for small radii or 45-degree segments; T6—Check for repeating instances of any geometric features (such as teeth on a gear).

Each of the above-described thought tokens provides the modeling agent with guidance as to how to convert the description received from the VLM 104 into a 3D CAD model. Each thought token prompts the modelling agent 106 to perform a corresponding action. In some embodiments, each action token may lead to generation of source code for various components that are present in the technical drawings. For example, for the thought token T1, a corresponding action (A1) that is performed is orienting the global coordinate system with the axes of symmetry; for the thought token T2, a corresponding action (A2) that is performed is creating base primitives. In some examples, base primitives (which may be 2D surface or a 3D solid) are created by extruding or revolving open or closed 2D sketches, respectively. In such examples, an open or closed sketch and an extrusion vector, or rotation vector may be defined using source code. Additionally, a 3D sweep path may be generated for the sketch. An example of this is a coil spring. For this example, the sweep path may be a helix, and the sketch to be extruded along this path may commonly be a circle or a rectangle. This allows the modelling agent 106 to set dimensions and coordinates of the sketch in the source code based on the semantic relationships and description extracted from the technical drawing by the VLM 104. Based on the dimensions and coordinates, the 2D or a 3D surface is generated from an open or closed sketch. An open sketch may be a curve that does not encircle a surface while a closed. In some embodiments, the open sketch is a line. When extruded along a vector, the line creates a planar (2D) surface. When the line is revolved about a parallel axis, a cylindrical (3D) surface is created. When swept along a path, a ribbon-like surface is created. A closed sketch may be used to create surfaces or solids in the model. A closed sketch is a sketch that encircles a surface. A closed sketch may be used to create a surface or a solid. In some embodiments, this is done by extruding, revolving, or sweeping the sketch. In some cases, it is checked (using one of the minimum threshold requirements), that these operations do not produce self-intersecting geometries. For example, a self-intersecting geometry may arise when revolving a sketch about an axis that intersects the sketch.

For the thought token T3, a corresponding action (A3) that is performed is creating secondary primitives and performing Boolean additions or subtractions. For example, a primary primitive may be a cylinder, and a secondary primitive may be a cuboid. The locating of the cuboid is such that it intersects the cylinder. Furthermore, the smallest surface of the cuboid is located on one of the end faces of the cylinder. The cuboid may be Boolean subtracted from the cylinder to create a keyway in the cylinder. For example, the Booleans additions and subtractions may be implemented in the source code that is generated for the technical drawings. For the thought token T4, a corresponding action (A4) that is performed is defining types, locations, and size parameters of various components that are part of the technical drawing, in the source code associated with the technical drawing. For the thought token T5, a corresponding action (A5) that is performed is applying the identified chamfers and fillets for small radii to corresponding edges (or conjoint surfaces) in the model. For the thought token T6, a corresponding action (A6) that is performed is defining circular or linear patterns of the repeating instances of the geometric feature with number of instances, spacing, and skipped instances, in the source code associated with the technical drawings.

In some embodiments, the thought tokens, starting at T1, are used sequentially. Each thought token Tₙ may be followed by a corresponding action token Aₙ. Each action token Aₙ may lead to generation of a portion of source code for converting the technical drawing to the 3D CAD model. Once all the thought tokens T1 through T6 are processed, source code for the 3D CAD model of the technical drawing is complete. The generated source code is provided to an open-source CAD software 108. The open-source CAD software 108 may use the source code generated by the modelling agent 106 to generate a CAD model associated with the technical drawing. In some embodiments, the open-source CAD software may generate parametric equations 110 associated with the technical drawing. In some embodiments, the parametric equations 110 may be used to render the 3D CAD model associated with the technical drawing. In some embodiments, the source code may be provided to the open-source 3D CAD software using API calls.

The generated 3D CAD model may be provided to the discriminating agent 112 to determine whether the 3D CAD model corresponds to the technical drawing that is received at the VLM 104 as input prompt 102. In some cases, the determination may be performed based on computing a probability that the generated 3D CAD model is a correct 3D CAD model of the technical drawing. In case the probability is greater than a predetermined threshold, the 3D CAD model is accepted, and in case the probability is less than the predetermined threshold, the discriminating agent 112 rejects the 3D CAD model and provides feedback to the modelling agent 106. The thought tokens of the modelling agent 106 may use the feedback to modify the source code associated with the 3D CAD model associated with the technical drawing. The updated source code may once again be provided to the open-source CAD software 108 to render the updated 3D CAD model. In some alternate embodiments, the open-source CAD software 108 may update the parametric equations 110. The updated parametric equations may be used to update the 3D CAD model associated with the technical drawing. The updated 3D CAD model may be provided to the discriminating agent 112, that determines whether the updated 3D CAD model matches the technical drawing. Once the discriminating agent 112 accepts the 3D CAD model, the parametric equations associated with the 3D CAD model is finalized and a final parametrized model 114 is generated associated with the technical drawing.

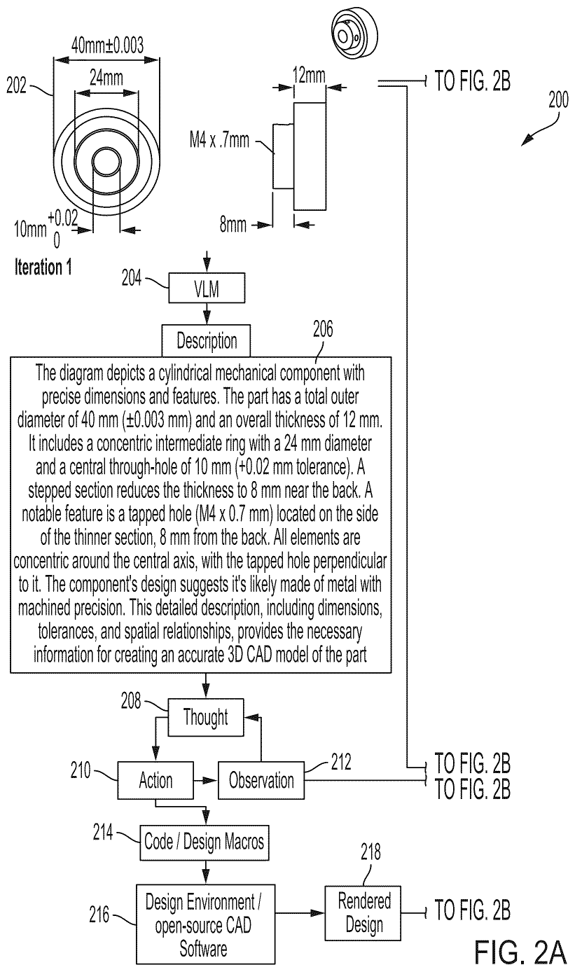

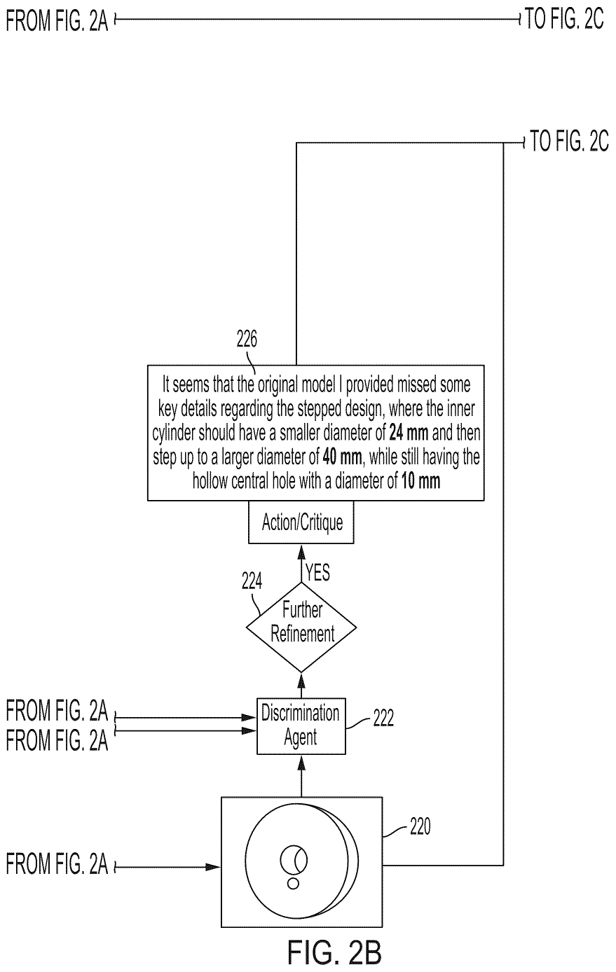

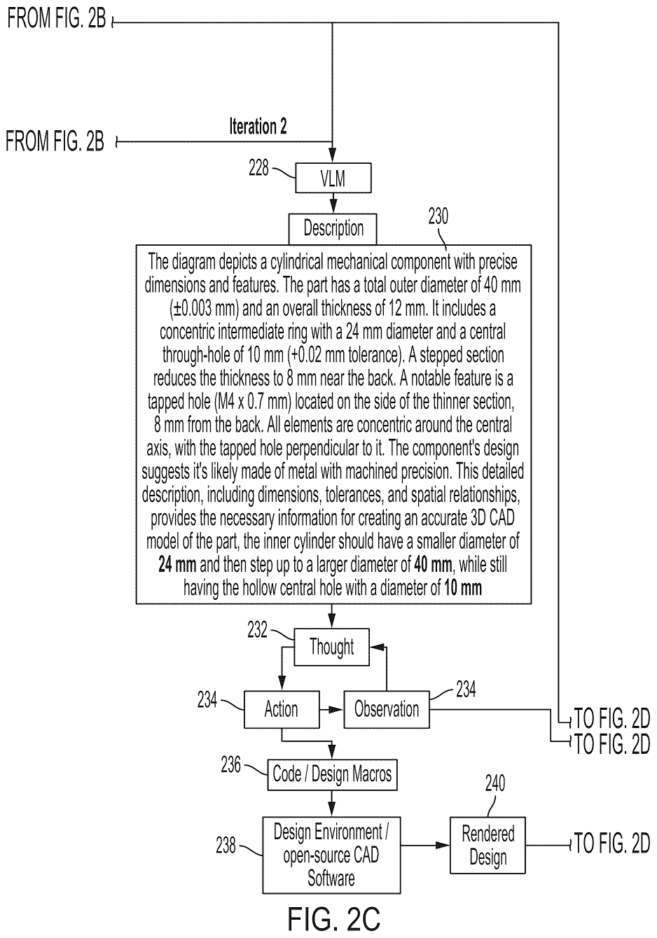

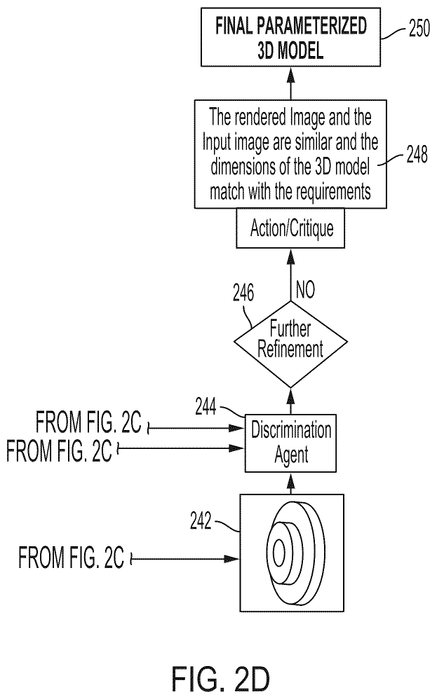

FIGS. 2A-2D illustrate a simplified diagram of a process of generating parametric three-dimensional (3D) CAD models, according to one or more examples of the present disclosure. In some embodiments, the process 200 may be performed by the system 100 of FIG. 1. However, it will be recognized that any of the following blocks may be performed in any suitable order and that the process 200 may be performed in any environment and by any suitable computing device and/or controller. As a running example, the FIGS. 2A-2D depict the process of generating a CAD model associated with the prompt shown in an input prompt 202.

At 204, the method 200 receives an input prompt 202. In some embodiments, the input prompt 202 may include a technical drawing for which a 3D CAD model is to be generated. The input prompt 202 with the technical drawing may be provided at a video-language-model (VLM). In some alternate embodiments, the input prompt may include a text description of a part that is to be generated. The input prompt 202 with the textual description may be provided to a large-language model (LLM).

At 206, the method 200 analyzes the input prompt 202 to generate a description. In some embodiments, a VLM may interpret the technical drawing input prompt 202 to determine a textual description. In such embodiments, the text description may include a description of various components, and semantic relationships between the various components of the technical drawing. In alternate embodiments, an LLM may interpret the text description provided as input to determine various components and determine semantic relationships between the various components of the part that is described in the text description.

At 208, the method 200 selects a thought token based on the description of the various components and the semantic relationship between the various components. As described with respect to FIG. 1, the thought token may be selected from the list of thought tokens T1-T6.

At 210, the method 200 performs an action associated with the selected thought token. For example, each thought token T1-T6 has a corresponding action (A1-A6) associated with it. The performance of each action (from A1-A6) generates a portion of source code for generating a 3D CAD model associated with the input prompt. In some embodiments, once a first action is performed, the method 200, at 212 may perform an observation based on the generated source code and the thought token. An example of an observation is running a check that minimum threshold requirements (described above) are met. Subsequently, the method 200 may move back to 208 to select a second thought token. In some cases, the thought tokens may be selected sequentially. For example, the first thought token that may be selected may be T1, and the second thought token that may be selected may be T2. In such cases, the corresponding actions for each of the thought tokens may also be performed sequentially, and an observation, at 212 may be generated after execution each action.

At 214, the method 200 may generate source code for generating a 3D CAD model for the input prompt 202, based on the execution of the action tokens (A1-A6). At 216, the method 200 may provide the generated source code to an open-source CAD software. The open-source CAD software may use the generated source code, at 218, to render a 3D CAD design, at 220, associated with the input prompt 202.

At 222, the method 200 may provide the 3D CAD design rendered at 220, observations from 212 and the input prompt 202 to a discriminating agent, at 222. For example, the discriminating agent 202 may be configured to determine whether further refinement may be needed for the generated 3D CAD model at 224. In some embodiments, the discriminating agent may determine, at 224, whether the 3D CAD design 220 corresponds to the input prompt 202. In some cases, the determination may be performed based on computing a probability that the generated 3D CAD model is a correct 3D CAD model of the input prompt 202. In some cases, the determination may be performed based on computing a probability that the generated 3D CAD model is a correct 3D CAD model of the technical drawing. In case the probability is greater than a predetermined threshold, the 3D CAD model is accepted, and in case the probability is less than the predetermined threshold, the discriminating agent, at 224 rejects the 3D CAD model, and the method at 226, provides feedback.

At 228, the method 200 may provide the feedback generated at 226, along with the input prompt 202 to the VLM or LLM.

At 230, the method 200 may instruct the VLM or LLM to analyze the feedback and update the description generated at 206.

At 232, the method 200 may select thought tokens (T1-T6) to update the 3D CAD model generated at 220. At 234, an action (A1-A6) corresponding to each selected thought token may be performed to update the 3D CAD model. Observations based on the executions of the action tokens may be generated at 234.

At 236, the method 200 revises the source code associated with the 3D CAD model for the input prompt 202. At 238, the method 200 provides the updated source code to the open-source CAD software at 238 to generate a revised rendered design 242, at 240. The method 244 provides the revised rendered design 242 to the discriminating agent at 244 along with the input prompt 202 and the observations generated at 234.

At 246, the method 200, using the discriminating agent determines whether the rendered updated 3D CAD model 242 needs further refinement. In case the method 200 determines whether the updated 3D CAD model 242 does not needs refinement, the method moves to 248 to finalize the 3D CAD model.

At 250, the method 200 determines parametric equations based on the rendered drawing 242. The parametric equations of the 3D model are provided as a response to the input prompt 202. In some embodiments, the parametric equations ensure that relations of various dimensions of the various components, such as aspect ratios, angular relationships, locations of features, are maintained.

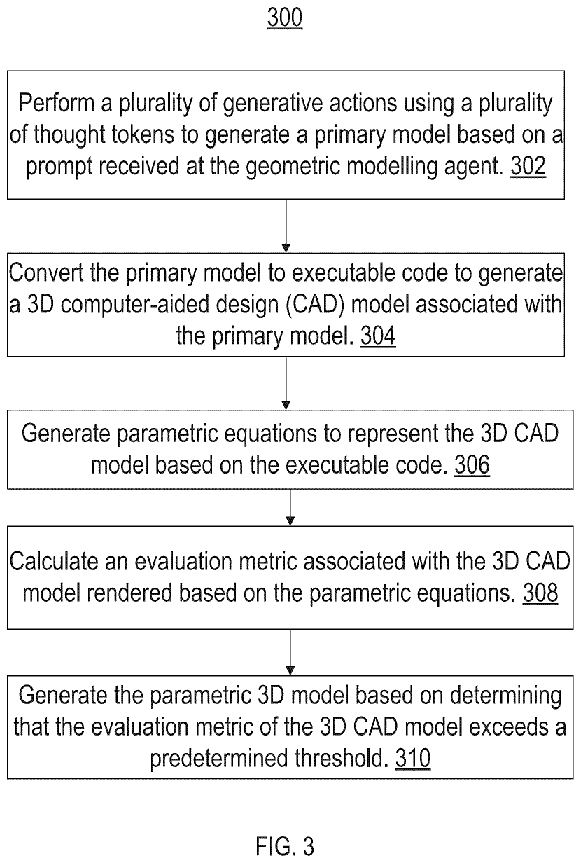

FIG. 3 illustrates a simplified diagram of a process of generating parametric three-dimensional (3D) CAD models, according to one or more examples of the present disclosure. In some embodiments, the process 200 may be performed by the system 100 of FIG. 1. However, it will be recognized that any of the following blocks may be performed in any suitable order and that the process 200 may be performed in any environment and by any suitable computing device and/or controller.

At 302, the method 300 performs a plurality of generative actions using a plurality of thought tokens to generate a primary model based on a prompt received at the geometric modelling agent. As described with respect to FIGS. 2A-2D, the prompt may include a technical drawing that is processed by a VLM to generate a text description of the 3D CAD model that is to be generated. The method 300 may analyze the text description to select a thought token from a list of thought tokens (T1-T6). A corresponding action token (A1-A6) associated with the thought token is executed to perform a generative action. Subsequently, the method 300 may select a second thought token, and execute a second corresponding action token associated with the second selected thought token. Each thought token performs a generative action to generate the primary model of the 3D CAD model that is to be generated.

At 304, the method 300 converts the primary model to executable code to generate a 3D computer-aided design (CAD) model associated with the primary model. For example, the method 300 may convert the primary model converted to executable code based on the execution of the action tokens (A1-A6). The method 200 may provide the generated source code to an open-source CAD software. The open-source CAD software may use the generated source code to render a 3D CAD design.

At 306, the method 300 generates parametric equations to represent the 3D CAD model based on the executable code. For example, the method 300 may generate parametric equations based on the rendered 3D CAD design.

At 308, the method 300 calculates an evaluation metric associated with the 3D CAD model rendered based on the parametric equations. For example, the method 300 may utilize a discriminating agent to determine whether the 3D CAD model generated based on the parametric equations needs refinement. In some cases, in order to determine that the 3D CAD model needs refinement, the method 300 may determine an evaluation metric. The evaluation metric may be a probability that the generated 3D CAD model is a correct 3D CAD model of the technical drawing received in the prompt at 302.

At 310, the method 300 generates the parametric 3D model based on determining that the evaluation metric of the 3D CAD model exceeds a predetermined threshold. For example, in case the probability determined at 308 is greater than a predetermined threshold, the 3D CAD model is accepted and the method 300 generates the parametric 3D CAD model, and in case the probability is less than the predetermined threshold, the method 300 rejects the 3D CAD model and provides feedback.

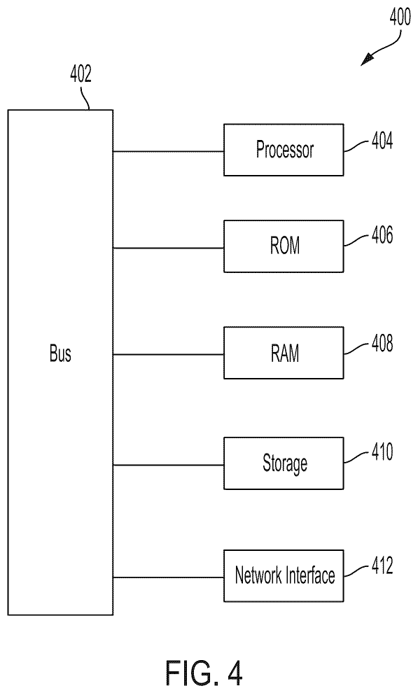

FIG. 4 is a block diagram of an exemplary system or device 400 within the environment 100 such as the controller 320. The system 300 includes a processor 404, such as a central processing unit (CPU), and/or logic, which executes computer executable instructions for performing the functions, processes, and/or methods described herein. In some examples, the computer executable instructions are locally stored and accessed from a non-transitory computer readable medium, such as storage 410, which may be a hard drive or flash drive. Read Only Memory (ROM) 406 includes computer executable instructions for initializing the processor 404, while the random-access memory (RAM) 408 is the main memory for loading and processing instructions executed by the processor 404. The network interface 412 may connect to a wired network or cellular network and to a local area network or wide area network. The system 300 may also include a bus 402 that connects the processor 404, ROM 406, RAM 408, storage 410, and/or the network interface 412. The components within the system 300 may use the bus 402 to communicate with each other. The components within the system 300 are merely exemplary and might not be inclusive of every component within the controller 320. Additionally, and/or alternatively, the system 300 may further include components that might not be included within every entity of environment 100. For instance, in some examples, the controller 320 might not include a bus 402.

While subject matter of the present disclosure has been illustrated and described in detail in the drawings and foregoing description, such illustration and description are to be considered illustrative or exemplary and not restrictive. Any statement made herein characterizing the invention is also to be considered illustrative or exemplary and not restrictive as the invention is defined by the claims. It will be understood that changes and modifications may be made, by those of ordinary skill in the art, within the scope of the following claims, which may include any combination of features from different embodiments described above.

The terms used in the claims should be construed to have the broadest reasonable interpretation consistent with the foregoing description. For example, the use of the article “a” or “the” in introducing an element should not be interpreted as being exclusive of a plurality of elements. Likewise, the recitation of “or” should be interpreted as being inclusive, such that the recitation of “A or B” is not exclusive of “A and B,” unless it is clear from the context or the foregoing description that only one of A and B is intended. Further, the recitation of “at least one of A, B and C” should be interpreted as one or more of a group of elements consisting of A, B and C, and should not be interpreted as requiring at least one of each of the listed elements A, B and C, regardless of whether A, B and C are related as categories or otherwise. Moreover, the recitation of “A, B and/or C” or “at least one of A, B or C” should be interpreted as including any singular entity from the listed elements, e.g., A, any subset from the listed elements, e.g., A and B, or the entire list of elements A, B and C.

What is claimed is:

1. A method for generating a three-dimensional (3D) model of a monolithic part, the method comprising:
a. performing a plurality of generative actions using a plurality of thought tokens to generate a primary model based on a prompt received at the geometric modelling agent;
b. converting the primary model to executable code to generate a 3D computer-aided design (CAD) model associated with the primary model;
c. generating parametric equations to represent the 3D CAD model based on the executable code;
d. calculating an evaluation metric associated with the 3D CAD model rendered based on the parametric equations; and
e. generating the parametric 3D model based on determining that the evaluation metric of the 3D CAD model exceeds a predetermined threshold.

2. The method of claim 1, wherein based on determining that the evaluation metric associated with the 3D CAD model is less than the predetermined threshold, the method further comprises:
generating feedback based on the calculated evaluation metric;
modifying the plurality of thought tokens to generate a modified plurality of thought tokens based on the feedback;
revising the executable code based on the modified plurality of thought token to obtain revised executable code;
regenerating the parametric equations based on the revised executable code to obtain revised parametric equations; and
calculating a revised evaluation metric associated with a new 3D CAD model rendered based on the revised parametric equations.

3. The method of claim 1, further comprising:
repeating steps a.-e., until the evaluation metric is less than the predetermined threshold.

4. The method of claim 1, wherein the 3D CAD model is generated by interfacing with an open-source CAD software using application programming interface (API) calls.

5. The method of claim 1, wherein generating the primary model based on the thought tokens comprises orienting a global system with axes of symmetry.

6. The method of claim 1, wherein generating the primary model based on the thought tokens comprises creating base primitives, and wherein the base primitives are created by extruding or revolving open or closed 3D sketches, respectively.

7. The method of claim 1, wherein generating the primary model based on the thought tokens comprises generating secondary primitives and performing Boolean operations.

8. The method of claim 1, wherein generating the primary model based on the thought tokens comprises defining types, locations, and size parameters of various components the monolithic part.

9. The method of claim 1, wherein generating the primary model based on the thought tokens comprises defining circular or linear patterns of repeating instances of a geometric feature with number of instances, spacing, and skipped instances.

10. A system for generating a three-dimensional (3D) model of a monolithic part, the system comprising:
a controller, configured to:
a. perform a plurality of generative actions using a plurality of thought tokens to generate a primary model based on a prompt received at the geometric modelling agent;
b. convert the primary model to executable code to generate a 3D computer-aided design (CAD) model associated with the primary model;
c. generate parametric equations to represent the 3D CAD model based on the executable code;
d. calculate an evaluation metric associated with the 3D CAD model rendered based on the parametric equations; and
e. generate the parametric 3D model based on determining that the evaluation metric of the 3D CAD model exceeds a predetermined threshold.

11. The system of claim 10, wherein based on determining that the evaluation metric associated with the 3D CAD model is less than the predetermined threshold, the controller is further configured to:
generate feedback based on the calculated evaluation metric;
modify the plurality of thought tokens to generate a modified plurality of thought tokens based on the feedback;
revise the executable code based on the modified plurality of thought token to obtain revised executable code;
regenerate the parametric equations based on the revised executable code to obtain revised parametric equations; and
calculate a revised evaluation metric associated with a new 3D CAD model rendered based on the revised parametric equations.

12. The system of claim 10, wherein the controller is further configured to:
repeat steps a.-e., until the evaluation metric is less than the predetermined threshold.

13. The system of claim 10, wherein the 3D CAD model is generated by interfacing with an open-source CAD software using application programming interface (API) calls.

14. The system of claim 10, wherein generating the primary model based on the thought tokens comprises orienting a global system with axes of symmetry.

15. The system of claim 10, wherein generating the primary model based on the thought tokens comprises creating base primitives, and wherein the base primitives are created by extruding or revolving open or closed 3D sketches, respectively.

16. The system of claim 10, wherein generating the primary model based on the thought tokens comprises generating secondary primitives and performing Boolean operations.

17. The system of claim 10, wherein generating the primary model based on the thought tokens comprises defining types, locations, and size parameters of various components the monolithic part.

18. The system of claim 10, wherein generating the primary model based on the thought tokens comprises defining circular or linear patterns of repeating instances of a geometric feature with number of instances, spacing, and skipped instances.

19. A tangible, non-transitory computer-readable medium for generating a three-dimensional (3D) model of a monolithic part, the computer-readable medium having instructions thereon, which, upon being executed by one or more processors, provides for execution of the following steps:
a. performing a plurality of generative actions using a plurality of thought tokens to generate a primary model based on a prompt received at the geometric modelling agent;
b. converting the primary model to executable code to generate a 3D computer-aided design (CAD) model associated with the primary model;
c. generating parametric equations to represent the 3D CAD model based on the executable code;
d. calculating an evaluation metric associated with the 3D CAD model rendered based on the parametric equations; and
e. generating the parametric 3D model based on determining that the evaluation metric of the 3D CAD model exceeds a predetermined threshold.

20. The non-transitory computer-readable medium of claim 19, wherein based on determining that the evaluation metric associated with the 3D CAD model is less than the predetermined threshold, the method further comprises:
generating feedback based on the calculated evaluation metric;
modifying the plurality of thought tokens to generate a modified plurality of thought tokens based on the feedback;
revising the executable code based on the modified plurality of thought token to obtain revised executable code;
regenerating the parametric equations based on the revised executable code to obtain revised parametric equations; and
calculating a revised evaluation metric associated with a new 3D CAD model rendered based on the revised parametric equations.
